(19) United States
(12) Patent Application Publication
(10) Pub. No.: US 2010/0288357 A1
(43) Pub. Date: Nov. 18, 2010

(54) HOUSING, ELECTRONIC DEVICE USING THE HOUSING, AND METHOD FOR MAKING THE HOUSING

(75) Inventors: CHIN-HSIEN LIANG, Shindian (TW); BEN-DING TSAO, Shindian (TW); WEN-LIN XIONG, Shenzhen City (CN); DIAN-MING ZHU, Shenzhen City (CN); JIANG-YING HU, Shenzhen City (CN); XIAN-MING WU, Shenzhen City (CN); YUE-JUN HE, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/693,631

(22) Filed: Jan. 26, 2010

(30) Foreign Application Priority Data
May 13, 2009 (CN) 200910302278.3

(51) Int. Cl. H01L 31/0368; H01L 31/0203; H01L 31/0216; H01L 31/18

(52) U.S. Cl. 136/258; 136/259; 438/64; 257/E31.119

(57) ABSTRACT

A housing comprises a transparent exterior coating, a photoelectric conversion coating bonded with the exterior coating and a substrate molded on the photoelectric conversion coating. The photoelectric conversion coating has electrode contacts thereon. The photoelectric conversion coating is used to convert light energy to electrical energy. The disclosure also describes an electronic device using the housing and a method for making the housing there.

### BACKGROUND

1. Technical Field

The present disclosure relates to housings, especially to a housing having photoelectric conversion property, an electronic device using the housing, and a method for making the housing.

2. Description of Related Art

Advances are being made to conserve energy by using solar energy to charge batteries in electronic products. However, the use of solar cells, even when very small, limit how much the electronic product can be reduced in size and weight. Commonly, solar chargers are separately employed to charge the products which adds to cost and is inconvenient.

Therefore, there is room for improvement within the art.

### BRIEF DESCRIPTION OF THE FIGURES

Many aspects of the housing can be better understood with reference to the following figures. The components in the figures are not necessarily drawn to scale, the emphasis instead being placed upon clearly illustrating the principles of the housing. Moreover, in the drawings like reference numerals designate corresponding parts throughout the several views.

FIG. 1 is a cross-sectional view of an exemplary embodiment of a housing;

FIG. 2 is a schematic view of an exemplary embodiment of an electronic device using the housing shown in FIG. 1.

### DETAILED DESCRIPTION

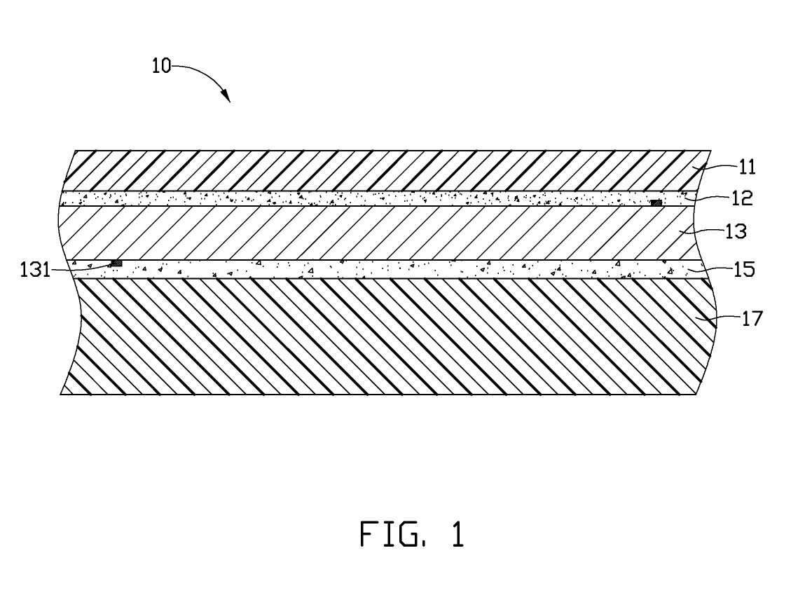

Referring to FIG. 1, in an exemplary embodiment, a housing 10 includes an exterior coating 11, a connecting coating 12 bonded with the exterior coating 11, a photoelectric conversion coating 13 bonded with the connecting coating 12, a protective coating 15 bonded with the photoelectric conversion coating 13, and a substrate 17 bonded with the protective coating 15. The coatings 11-15 are applied sequentially to the interior of a mold and are then transferred to the substrate 17 in a molding process to form the housing 10.

The exterior coating 11 is a transparent plastic coating having a thickness of about 0.175 mm. The exterior coating 11 may undergo a surface treatment to make its surface smoother once the housing 10 is molded.

The connecting coating 12 may be formed on one surface of the exterior coating 11 by daubing glue. The connecting coating 12 can enhance the bonding between the exterior coating 11 and the photoelectric conversion coating 13.

The photoelectric conversion coating 13 may be a semiconductor polycrystalline silicon wafer having a thickness of about 0.15-0.25 mm. The photoelectric conversion coating 13 has electrode contacts 131 thereon. The electrode contacts 131 are disposed on the opposite sides of the photoelectric conversion coating 13 by printing conductive silver slurry or conductive aluminum slurry. The photoelectric conversion coating 13 can absorb light energy. The light energy energizes and frees electrons of the semiconductor polycrystalline silicon wafer. The free electrons gather to one side of the semiconductor polycrystalline silicon wafer to produce a potential difference. When the electrode contacts 131 are electrically connected to a circuit of an electronic device, an electrical current will be generated due to the potential difference, as a result, electric energy is supplied to the electronic device.

The protective coating 15 may be an adhesive coating formed on the exposed surface of the photoelectric conversion coating 13 by spraying. The main material contained in the adhesive may be synthetic resin. The thickness of the protective coating 15 is about 0.02-0.03 mm.

The substrate 17 may be a plastic coating molded on the protective coating 15. The plastic of molding the substrate 17 may be selected from a group consisting of polyethylene (PE), polycarbonate (PC), polymethyl methacrylate (PMMA), acrylonitrile-butadiene-styrene (ABS), and polyethylene terephthalate (PET).

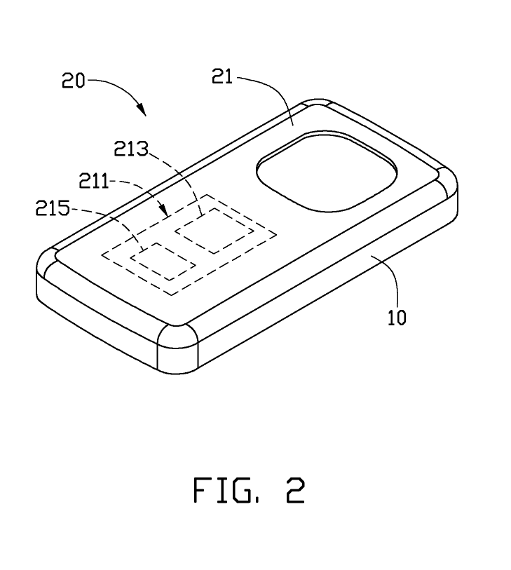

Referring to FIG. 1 and FIG. 2, in an exemplary embodiment, an electronic device 20 includes a main body 21 and a housing 10 fixed to the maim body 21. The main body 21 includes a mainboard 211 and a storage battery 213. The mainboard 211 is integrated with a power supply controller unit 215. The storage battery 213 can supply power to the electronic device 20. The housing 10 includes an exterior coating 11, a connecting coating 12 bonded with the exterior coating 11, a photoelectric conversion coating 13 bonded with the connecting coating 12, a protective coating 15 bonded with the photoelectric conversion coating 13 and a substrate 17 bonded with the protective coating 15. The coatings 11-15 are applied sequentially to the interior of a mould and are then transferred to the substrate 17 in a molding process to form the housing 10. The photoelectric conversion coating 13 may be a semiconductor polycrystalline silicon wafer. The photoelectric conversion coating 13 has electrode contacts 131 thereon. The electrode contacts 131 can be electrically connected with the power supply controller unit 215 of the mainboard 211. The photoelectric conversion coating 13 absorbs light energy. The light energy energizes and frees electrons of the semiconductor polycrystalline silicon wafer. The free electrons gather to one side of the semiconductor polycrystalline silicon wafer to produce a potential difference. When the electrode contacts 131 are electrically connected to the power supply controller unit 215, an electrical current will be generated in the electronic device 20 due to the potential difference, as a result, electrical energy is generated to store up in the storage battery 213 to supply power to the electronic device 20.

The exemplary electronic device 20 may be a mobile phone, a PDA, a camera, a MP3 or MP4 player.

A method for making the housing 10, in the exemplary embodiment, may comprise: molding a transparent exterior coating; manufacturing a photoelectric conversion coating and bonding it with the exterior coating; providing electrode contacts on the photoelectric conversion coating; and molding a substrate onto the photoelectric conversion coating.

Referring to FIG. 1, an exterior coating 11 is molded. The material of molding the exterior coating 11 is selected from a group consisting of polypropylene (PP), polyamide (PA), polycarbonate (PC), polymethyl methacrylate (PMMA) and polyethylene terephthalate (PET). The exterior coating 11 may undergo a surface treatment for smoothening its surface smoother after the housing 10 is made.

A connecting coating 12 is formed on one surface of the exterior coating 11 by daubing glue.

A photoelectric conversion coating 13 is manufactured. The photoelectric conversion coating 13 may be a semiconductor polycrystalline silicon wafer made by a normal method for making silicon wafers. The area of each surface of the photoelectric conversion coating 13 and the area of each surface of the exterior coating 11 may be the same.

Electrode contacts 131 are defined on the photoelectric conversion coating 13. The electrode contacts 131 may be disposed on the opposite sides of the photoelectric conversion coating 13. The electrode contacts 131 may be formed by printing conductive silver slurry or conductive aluminum slurry. After the electrode contacts 131 are formed, the photoelectric conversion coating 13 is bonded to the connecting coating 12 at a temperature of about 90-100° C.

A protective coating 15 is formed on the exposed surface of the photoelectric conversion coating 13. The protective coating 15 may be an adhesive coating formed by spraying. The main material contained in the adhesive may be synthetic resin.

The coatings 11-15 are then applied to the interior of a mould and the substrate 17 is molded onto the protective coating 15 to form the housing 10. The plastic of molding the substrate 17 may be selected from a group consisting of polyethylene (PE), polycarbonate (PC), polymethyl methacrylate (PMMA), acrylonitrile-butadiene-styrene (ABS), and polyethylene terephthalate (PET).

It should be understood, the connecting coating 12 is not necessary. The photoelectric conversion coating 13 can be directly formed on the surface of the exterior coating 11 by a hot pressing process.

It should be understood, the protective coating 15 is not necessary. The substrate 17 can be directly molded on the photoelectric conversion coating 13.

The exemplary electronic device 20 has a photoelectric conversion coating 13 which is small in size and is easy to be tightly bonded with the connecting coating 12 and the protective coating 15 to convert the light energy to electrical energy to supply power to the electronic device 20 more efficiently.

It should be understood, however, that even though numerous characteristics and advantages of the present embodiments have been set forth in the foregoing description, together with details of functions of the embodiments, the disclosure is illustrative only, and changes may be made in detail within the principles of the disclosure to the full extent indicated by the broad general meaning of the terms in which the appended claims are expressed.

What is claimed is:

1. A housing, comprising:
a transparent exterior coating;
a photoelectric conversion coating bonded with the exterior coating, the photoelectric conversion coating having electrode contacts thereon and being used to convert light energy to electric energy; and
a substrate molded on the photoelectric conversion coating.

2. The housing as claimed in claim 1, wherein the photoelectric conversion coating is a semiconductor polycrystalline silicon wafer having a thickness of about 0.15-0.25 mm.

3. The housing as claimed in claim 1, wherein the housing further includes a connecting coating disposed between the exterior coating and the photoelectric conversion coating.

4. The housing as claimed in claim 3, wherein the housing further includes a protective coating disposed between the photoelectric conversion coating and the substrate.

5. The housing as claimed in claim 4, wherein the protective coating is an adhesive coating formed by spraying.

6. The housing as claimed in claim 4, wherein the substrate is molded on the protective coating.

7. An electronic device, comprising:
a main body, the main body including a mainboard and a storage battery, the mainboard being integrated with a power supply controller unit thereon, the storage battery supplying power to the electronic device; and
a housing fixed upon the main body, the housing including a transparent exterior coating and a substrate;
wherein the housing further includes a photoelectric conversion coating disposed between the exterior coating and the substrate, the photoelectric conversion coating has electrode contacts thereon and being used to convert light energy to electric energy; the electrode contacts electrically connected with the power supply controller unit of the mainboard, the photoelectric conversion coating absorbs light energy and converts the light energy to electrical energy for storage in the storage battery.

8. The electronic device as claimed in claim 7, wherein the photoelectric conversion coating is a semiconductor polycrystalline silicon wafer having a thickness of about 0.15-0.25 mm.

9. The electronic device as claimed in claim 7, wherein the housing further includes a connecting coating disposed between the exterior coating and the photoelectric conversion coating.

10. The electronic device as claimed in claim 9, wherein the housing further includes a protective coating disposed between the photoelectric conversion coating and the substrate.

11. The electronic device as claimed in claim 10, wherein the protective coating is an adhesive coating formed by spraying.

12. The electronic device as claimed in claim 10, wherein the substrate is molded on the protective coating.

13. A method for making a housing, including:
molding a transparent exterior coating;
manufacturing a photoelectric conversion coating and bonding it with the exterior coating;
providing electrode contacts on the photoelectric conversion coating; and
molding a substrate on the photoelectric conversion coating.

14. The method as claimed in claim 13, wherein the photoelectric conversion coating is a semiconductor polycrystalline silicon wafer.

15. The method as claimed in claim 13, wherein the method further includes a step of forming a connecting coating onto the exterior coating by daubing glue after the exterior coating is molded; the photoelectric conversion coating is bonded with the connecting coating.

16. The method as claimed in claim 13, wherein the method further includes a step of spraying a protective coating onto the photoelectric conversion coating before the substrate is molded.

17. The method as claimed in claim 16, wherein the protective coating is an adhesive coating.

18. The method as claimed in claim 16, wherein the substrate is molded on the protective coating.
